(19) United States
(12) Patent Application Publication
(10) Pub. No.: US 2025/0159870 A1
(43) Pub. Date: May 15, 2025

(54) SEMICONDUCTOR STRUCTURE

(71) Applicant: Fujian Jinhua Integrated Circuit Co., Ltd., Quanzhou City (CN)

(72) Inventor: Li-Wei Feng, Quanzhou City (CN)

(73) Assignee: Fujian Jinhua Integrated Circuit Co., Ltd., Quanzhou City (CN)

(21) Appl. No.: 18/418,325

(22) Filed: Jan. 21, 2024

(30) Foreign Application Priority Data
Nov. 13, 2023 (CN) 202311507995.6
Nov. 13, 2023 (CN) 202323061192.0

(51) Int. Cl. H10B 12/00

(52) U.S. Cl. CPC H10B 12/50; H10B 12/315

(57) ABSTRACT

A semiconductor structure includes a substrate and a connecting layer disposed on the substrate. The connecting layer includes a plurality of connection pads, a dam structure, a plurality of first extension pads and a plurality of second extension pads. The connection pads are arranged along a first direction and a third direction to form a connection pad array. The dam structure is disposed at a side of the connection pad array and extends along the first direction. The plurality of first extension pads and the plurality of second extension pads extend along a second direction, and are alternately arranged between the dam structure and the connection pad array along the first direction and aligned with the plurality of connection pads along the second direction, wherein the plurality of first extension pads and the plurality of second extension pads are separated from the dam structure.

### BACKGROUND OF THE INVENTION

### 1. Field of the Invention

The present invention generally relates to a semiconductor structure, and more particularly, to a semiconductor structure including a connecting layer.

### 2. Description of the Prior Art

A dynamic random access memory (DRAM) is a kind of volatile memory, which includes an array region consisting of a plurality of memory cells and a peripheral area consisting of a control circuit. Each memory cell includes a transistor and a capacitor electrically connected to the transistor, and the transistor controls storage or release of charges into or from the capacitor to achieve the purpose of data storage. The control circuit can address each memory cell through word lines (WL) and bit lines (BL), which are distributed all over the array area and are electrically connected to the memory cells, thereby controlling data access to the memory cells.

In order to obtain enhanced chip density, the structure of the memory cells has been developed towards a three-dimensional configuration, e.g., buried word lines and stacked capacitors. According to the technology of stacked capacitors, capacitors of the memory cells are disposed above the substrate and electrically connected to the transistors in the substrate in a vertical direction through plug structures and connection pad structures, thereby saving the substrate area occupied by the capacitors. In addition, it is easy to increase capacitance by increasing height of an electrode plate of the capacitor. However, there are still some technical problems that need to be further solved. For example, it is necessary to ensure reliability of the stacked capacitor structure and reduce current leakage in the peripheral area.

### SUMMARY OF THE INVENTION

An object of the present invention is to provide a semiconductor structure including a connecting layer for producing a three-dimensional DRAM. The connecting layer includes connection pads disposed in a cell region and a dam structure disposed in a peripheral region, and may further optionally include extension pads between the dam structure and the connection pads. The connection pads are used for accomplishing electric connection in a vertical direction between stacked capacitors and transistors in the substrate. The design of dam structure or dam structure annexed with connection pads can ameliorate structural defects in the peripheral region and improve reliability of the device.

An embodiment of the present invention provides a semiconductor structure, which includes a substrate and a connecting layer disposed on the substrate. The connecting layer includes a plurality of connection pads, a dam structure, a plurality of first extension pads and a plurality of second extension pads. The connection pads are arranged along a first direction and a third direction to form a connection pad array. The dam structure is disposed at a side of the connection pad array and extends along the first direction. The plurality of first extension pads and the plurality of second extension pads extend along a second direction, and are alternately arranged between the dam structure and the connection pad array along the first direction and aligned with the plurality of connection pads along the second direction, wherein the plurality of first extension pads and the plurality of second extension pads are separated from the dam structure.

Another embodiment of the present invention provides a semiconductor structure, which includes a substrate and a connecting layer disposed on the substrate. The connecting layer includes a plurality of first connection pads, a first dam structure, a second dam structure and a plurality of second connection pads. The first connection pads are arranged along a first direction and a third direction to form a connection pad array, wherein in the first direction, the plurality of first connection pads have a shortest gap with a first distance between two adjacent ones thereof. The first dam structure is disposed at a first side of the connection pad array and extends along the first direction. The second dam structure is disposed at a second side of the connection pad array and extends along the third direction. The second connection pads are arranged between the connection pad array and the first dam structure along the first direction and separated from the first dam structure, wherein in the first direction, the plurality of second connection pads have a shortest gap with a second distance between two adjacent ones thereof, and the second distance is greater than the first distance.

A further embodiment of the present invention provides a semiconductor structure, which includes a substrate, an interlayer dielectric layer disposed on the substrate and a connecting layer disposed on the interlayer dielectric layer. The substrate includes a cell region and a peripheral region adjacent to each other. The interlayer dielectric layer includes a first dielectric layer disposed in the cell region and a second dielectric layer disposed in the peripheral region. The connecting layer is disposed in the cell region and includes a plurality of connection pads disposed in the cell region, a dam structure disposed in the peripheral region, an extension pad disposed between the plurality of connection pads and the dam structure, and an insulating material isolating the dam structure, the connection pads and the extension pad from one another. The semiconductor structure further includes a first plug structure disposed in the second dielectric layer and between the extension pad and the dam structure, wherein a lower portion of the first plug structure is formed of a semiconductor material, an upper portion of the first plug structure is formed of a conductive material, and a top surface of the first plug structure is completely covered by the insulating material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic top view illustrating a partial area of a semiconductor structure according to an embodiment of the present invention.

FIG. 2 is a schematic top view illustrating a partial area of a semiconductor structure according to another embodiment of the present invention.

FIG. 3 is a schematic top view illustrating a partial area of a semiconductor structure according to a further embodiment of the present invention.

FIG. 4 is a schematic top view illustrating a partial area of a semiconductor structure according to yet another embodiment of the present invention.

FIG. 5 is a schematic top view illustrating a partial area of a semiconductor structure according to still another embodiment of the present invention.

FIG. 6 is a cross-sectional view taken along a cut line AA′ shown in FIG. 1, which schematically illustrates a partial area of a semiconductor structure according to an embodiment of the present invention.

FIG. 7 is a cross-sectional view taken along a cut line AA′ shown in FIG. 1, which schematically illustrates a partial area of a semiconductor structure according to another embodiment of the present invention.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

In order to make those of ordinary skilled in the art readily understand the invention and for simplifying the drawings, several drawings in this disclosure only depict a part of the semiconductor structure, and specific elements in the drawings are not drawn to actual scale. In addition, the number and size of each element in the drawings are only for illustration and are not used to limit the scope of the disclosure. It is understood by those of ordinary in the art that the expressions “on”, “above”, “below”, “upper”, “lower”, “over”, “under”, etc. are used for indicating relative positions of the elements, and all the elements can be turned over while still presenting the same structure. Both configurations should belong to the scope disclosed in this specification.

For facilitating descriptions and understanding of the semiconductor structure according to the present invention, spatial reference directions such as a first direction D1, a second direction D2, a third direction D3 and a fourth direction D4 are given in the drawings, wherein the first direction D1, the second direction D2 and the third direction D3 are parallel to a surface of the substrate, and the first direction D1 and the third direction D3 are perpendicular to each other and both different from the second direction D2. The angle between the second direction D2 and the third direction D3 may be between 15 degrees and 75 degrees, but it is not limited thereto. The fourth direction D4 is perpendicular to the surface of the substrate.

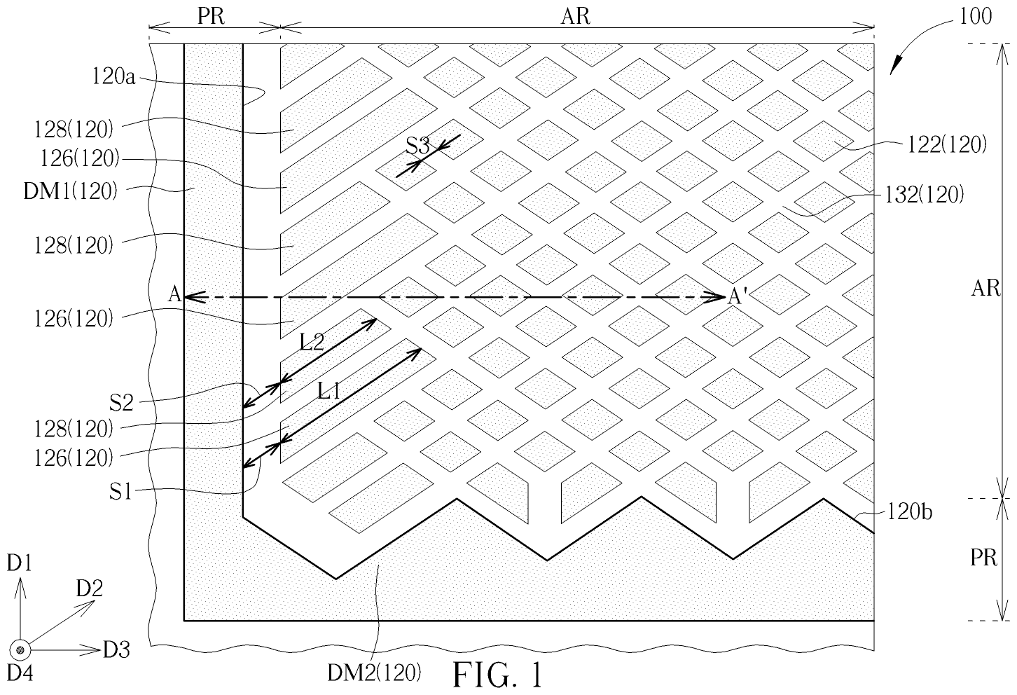

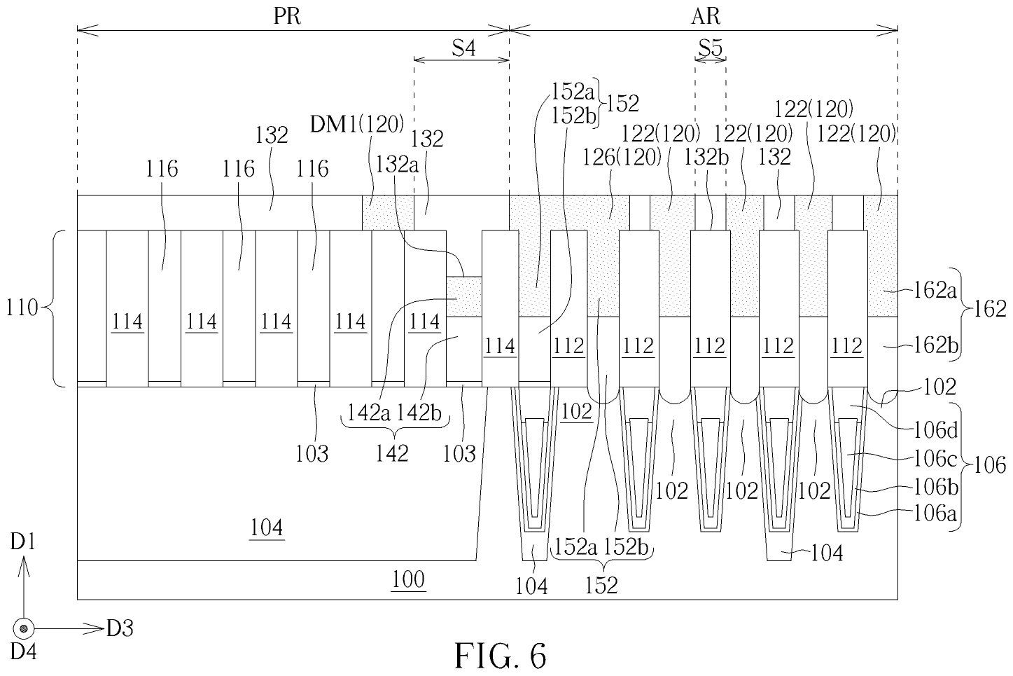

Please refer to FIG. 1 and FIG. 6. FIG. 1 is a schematic top view illustrating a partial area of a semiconductor structure according to an embodiment of the present invention. FIG. 6 is a cross-sectional view taken along a cut line AA′ shown in FIG. 1, which schematically illustrates a partial area of a semiconductor structure according to an embodiment of the present invention. The cut line AA′ is a straight line extending in the third direction D3. The semiconductor structure according to the present invention may be used to produce a DRAM including stacked capacitor structures. The stacked capacitor structures (not shown) are disposed on a connecting layer 120 and electrically connected to the transistors in the substrate 100 through connection pads 122 of the connecting layer 120 and plug structures 162 disposed in an interlayer dielectric layer 110. The semiconductor structure according to the present invention may also be applied to other types of memory devices without departing from the spirit of the present invention.

The semiconductor structure includes a substrate 100, an interlayer dielectric layer 110 disposed on the substrate 100 and a connecting layer 120 disposed on the interlayer dielectric layer 110. The substrate 100 may be, for example but not limited to, a silicon substrate, an epitaxial silicon substrate, a silicon germanium substrate, a silicon carbide substrate or a silicon-on-insulator (SOI) substrate. The substrate 100 includes a cell region AR and a peripheral region PR. The cell region AR may also be referred to as an array region, where memory cells are disposed. The peripheral region PR is disposed at and contiguous with an outward side of the cell region AR for dividing the cell region AR from other circuit region of the substrate 100. In some embodiments, the peripheral region PR surrounds outside the entire cell region AR. In some embodiments, the peripheral region PR may also be a region where word lines and bit lines for controlling operations of the memory cells are electrically connected to the peripheral circuit.

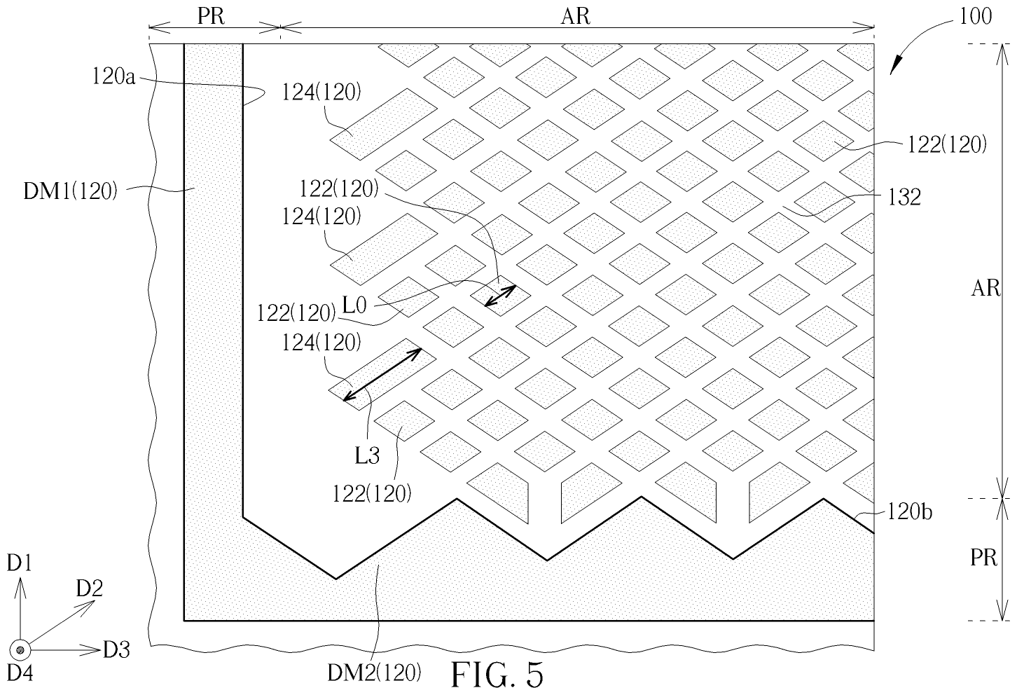

The substrate 100 may further include a plurality of isolation structures 104 and a plurality of active areas 102, which are defined in the substrate 100 with the plurality of isolation structures 104. The isolation structures 104 may be, for example but not limited to, shallow trench isolation (STI) structure, which may include a material of single layer or multiple layers. Suitable dielectric material includes, for example but not limited to, silicon oxide (SiO₂), silicon nitride (SiN), silicon oxynitride (SiON), silicon nitride (SiCN), nitrogen-doped silicon carbide (NDC), low-k dielectric material such as fluorinated silica glass (FSG), silicon carbide oxide (SiCOH), spin-on glass, porous low-k dielectric material, organic polymer dielectric material, or a combination of the above materials. As shown in FIG. 5, the cell region AR includes a plurality of active areas 102 divided by the isolation structures 104. These active areas 102 are disposed therein transistors of the memory cells, and the peripheral region PR is disposed therein the isolation structures 104.

A plurality of word line structures 106 are disposed in the substrate 100, extend along a first direction D1, and cut through the isolation structures 104 and the active areas 102. A method for forming the word line structures 106 may include forming word line trenches cutting through the isolation structures 104 and the active areas 102 in the substrate 100, and then forming a gate insulating layer 106a overlying a bottom surface and a sidewall of each of the word line trenches. Subsequently, a work function metal layer 106b and a conductive layer 106c are formed to fill a lower part of the word line trench, and then an insulating cap layer 106d is formed to fill an upper part of the word line trench. The insulating cap layer 106d and the gate insulating layer 106a may both include dielectric materials, for example but not limited to, silicon oxide (SiO₂), silicon nitride (SiN), silicon oxynitride (SiON), silicon nitride (SiCN), high-k dielectric material, or a combination of the above materials. A material of the work function metal layer 106b may include an n-type work function metal such as titanium aluminide (TiAl), zirconium aluminide (ZrAl), tungsten aluminide (WAl), tantalum aluminide (TaAl), hafnium aluminide (HfAl) or titanium aluminum carbide (TiAlC), or may include a p-type work function metal such as titanium nitride (TiN), tantalum nitride (taN) or tantalum carbide (TaC), but it is not limited thereto. The conductive layer 106c may include a metal material such as tungsten (W), copper (Cu), aluminum (Al), titanium (Ti), tantalum (Ta), a compound, an alloy and/or a composite layer of the above-mentioned metal, but it is not limited thereto. It should be understood that other circuit elements and structures, e.g., bit lines and interconnect structures, may be further disposed in the substrate 100 or on the substrate 100, but are not shown in the drawings for simplification.

The interlayer dielectric layer 110 is disposed between the substrate 100 and the connecting layer 120 and include first dielectric layers 112 in the cell region AR and second dielectric layers 114 and third dielectric layers 116 in the peripheral region PR, wherein the second dielectric layers 114 and the third dielectric layers 116 are alternately arranged along a third direction D3. The first dielectric layers 112, the second dielectric layers 114 and the third dielectric layers 116 include respective dielectric materials, for example but not limited to, silicon oxide (SiO₂), silicon nitride (SiN), silicon oxynitride (SiON), silicon nitride (SiCN) or nitrogen-doped silicon carbide (NDC). According to an embodiment of the present invention, the first dielectric layers 112 and the second dielectric layers 114 are formed of the same material, e.g., silicon nitride (SiN), and the third dielectric layers 116 are formed of a material different from the material of the first dielectric layers 112 and the second dielectric layers 114, e.g., silicon oxide (SiO₂).

In some embodiments, as shown in FIG. 6, the interlayer dielectric layer 110 may further include insulating layers 103 disposed between the third dielectric layers 116 and the isolation structures 104 for isolating them and keeping them out of direction contact. The insulating layers 103 may be formed of a material of a single layer or multiple layers. Suitable material may include, for example but not limited to, silicon oxide (SiO₂), silicon nitride (SiN), silicon oxynitride (SiON), silicon nitride (SiCN) and nitrogen-doped silicon carbide (NDC). According to an embodiment of the present invention, the insulating layers 103 are composite layers formed of silicon oxide-nitride-oxide. The bottom surfaces of the second dielectric layers 114 are in direct contact with the isolation structures 104.

The connecting layer 120 is disposed on the interlayer dielectric layer 110 and include a plurality of connection pads 122 in the cell region AR and a first dam structure DM1 and a second dam structure DM2 in the peripheral region PR, first extension pads 126 and second extension pads 128 disposed in the cell region AR and between the connection pads 122 and the first dam structure DM1, and an insulating material 132 disposed among the connection pads 122, the first dam structure DM1, the second dam structure DM2, the first extension pads 126 and second extension pads 128 for isolation of these structures.

The connection pads 122 are allocated along the first direction D1 and the third direction D3 to form a connection pad array for electric connection to bottom electrodes of the capacitor structures. The first dam structure DM1 and the second dam structure DM2 respectively extend along the first direction D1 and the third direction D3 and are disposed at a first side, e.g., the left side as shown, and a second side, e.g., the lower side as shown, and the first dam structure DM1 and the second dam structure DM2 are interconnected to each other. The first dam structure DM1 has an inner edge 120a adjacent to the first extension pads 126 and the second extension pads 128 and having a linear contour, and the second dam structure DM2 has an inner edge 120b adjacent to the extension pad array and having a wavy contour. As shown in FIG. 1, the first extension pads 126 and the second extension pads 128 are shaped as long strips, which lengthwise extend along the second direction D2, and alternately arranged along the first direction D1 between the first dam structure DM1 and the connection pad array. The first extension pads 126 and the second extension pads 128 are aligned with the connection pads 122 in the second direction D2. The connection pads 122 are configured as island structures. In the second direction D2, the first extension pads 126 have a length L1, the second extension pads 128 have a length L2, an end portion of the first extension pads 126 is spaced from the inner edge 120a of the first dam structure DM1 with a distance S1, an end portion of the second extension pads 128 is spaced from the inner edge 120a of the first dam structure DM1 with a distance S2, and the connection pads 122 are spaced from each other with a distance S3. In some embodiments, the length L1 is not equal to the second length L2, while the distance S1 is substantially equal to the distance S2 and greater than the distance S3. Along the cut line AA′, as shown in FIG. 6, a spacing distance S4 between the first extension pads 126 and the first dam structure DM1 is greater than a spacing distance S5 between adjacent connection pads 122.

A method of forming the connecting layer 120 may include forming a conductive layer (not shown), and then performing an etching process on the conductive layer to transform the conductive layer into the connection pads 122, the first dam structure DM1, the second dam structure DM2, the first extension pads 126 and the second extension pads 128. Subsequently, an insulating layer 132 is formed to overly the interlayer dielectric layer 110 and fills in gaps among the connection pads 122, the first dam structure DM1, the second dam structure DM2, the first extension pads 126 and the second extension pads 128 for surface planarization. The material of the conductive layer may include a metal such as tungsten (W), copper (Cu), aluminum (Al), titanium (Ti), tantalum (Ta), a compound, an alloy and/or a composite layer of the above-mentioned metal, but it is not limited thereto. According to an embodiment of the present invention, the material of the conductive layer includes tungsten (W). The insulating layer 132 may include, for example but not limited to, silicon oxide (SiO₂), silicon nitride (SiN), silicon oxynitride (SiON), silicon nitride (SiCN), nitrogen-doped silicon carbide (NDC), low-k dielectric material such as fluorinated silica glass (FSG), silicon carbide oxide (SiCOH), spin-on glass, porous low-k dielectric material, organic polymer dielectric material, or a combination of the above materials. According to an embodiment of the present invention, the insulating layer 132 includes silicon nitride (SiN).

A plurality of plug structures are disposed in the interlayer dielectric layer 110 and include at least one first plug structure 142 disposed in the second dielectric layer 114 in the peripheral region PR, at least one second plug structure 152 disposed in the first dielectric layer 112 in the cell region AR, and a plurality of third plug structures 162 disposed in the first dielectric layer 112 in the cell region AR. The first plug structure 142 shown in FIG. 6 is disposed on the isolation structure 104 between the first dam structure DM1 and an extension pad e.g., the first extension pad 126. An insulating layer 103 is optionally disposed between the first plug structure 142 and the isolation structure 104, so as to keep the first plug structure 142 out of direct contact with the isolation structure 104. A top surface of the first plug structure 142 is completely covered by the insulating layer 132. The second plug structure 152 is close to an edge of the cell region AR and optionally disposed on the isolation structure 104, the insulating cap layer 106d of the word line structure 106 or the active area 102. The bottom of the second plug structure 152 is in direct contact with the structures thereunder, or is isolated from and not in direct contact with the structures thereunder by an insulating layer 103. For example, FIG. 6 schematically shows two second plug structures 152. The left one of the two second plug structures 152 is disposed above the insulating cap layer 106d, and its bottom is isolated from and not in direct contact with the insulating cap layer 106d by the insulating layer 103. The right one of the two second plug structures 152 is disposed on the active area 102, and its bottom is in direct contact with the active area 102. Top surfaces of the second plug structures 152 are covered and in direct contact with an extension pad, e.g., the first extension pad 126 shown in FIG. 6. The third plug structures 162 are disposed on the active area 102, and their bottoms are in direct contact with the active area 102, and top surfaces thereof are covered and in direct contact with the connection pads 122. In consideration of functionality, the third plug structures 162 are actual conducting plugs for electrically connecting the active area 102 with the connecting pads 122, while the first plug structure 142 and the second plug structures 152 are dummy plugs designed according to process requirements for adjusting pattern density and improving manufacturing quality.

Upper portions and lower portions of the first plug structure 142, the second plug structures 152 and the third plug structures 162 are made of different materials. According to an embodiment of the present invention, the lower portion 142b of the first plug structure 142, the lower portions 152b of the second plug structures 152 and the lower portions 162b of the third plug structures 162 may include the same semiconductor material. Suitable semiconductor material may include, for example but not limited to, crystalline silicon, polycrystalline silicon, amorphous silicon, doped silicon, silicon germanium (SiGe), and any other suitable semiconductor material. The upper portion 142a of the first plug structure 142, the upper portions 152a of the second plug structures 152 and the upper portions 162a of the third plug structures 162 may include the same conductive material. Suitable conductive material may include, for example but not limited to, metal such as tungsten (W), copper (Cu), aluminum (Al), titanium (Ti), tantalum (Ta), a compound, an alloy and/or a composite layer of the above-mentioned metal.

In some embodiments, the first plug structure 142, the second plug structures 152 and the third plug structures 162 may further include interface layers (not shown) disposed between respective lower portions and upper portions. The material of the interface layer may include, for example but not limited to, metal, metal silicide or metal nitride, e.g., titanium (Ti), titanium nitride (TiN), tungsten silicide (WSi), cobalt silicide (CoSi), tungsten nitride (WN), etc.

In some embodiments, the upper portion 142a of the first plug structure 142, the upper portions 152a of the second plug structures 152 and the upper portions 162a of the third plug structures 162 are formed by filling the conductive layer (not shown), which is also used to form the connection pads 122, the dam structures and the extension pads, into openings of the plug structures (not shown), and thus include the same material, e.g., tungsten (W), as the connection pads 122, the dam structures and the extension pads. The upper portions 152a of the second plug structures 152 shown in FIG. 6 are configured to be integrated with an extension pad, e.g., the first extension pad 126, and the upper portions 162a of the third plug structures 162 are configured to be integrated with connection pads, e.g., the connection pads 122. It is to be noted that the upper portions 152a of the second plug structures 152 may be configured to be integrated with different extension pads. Alternatively, as shown in FIG. 6, the second plug structures 152 may be disposed on the substrate 100 as a pair, and the upper portions 152a of the second plug structures 152 are configured to be integrated with the same extension pad, e.g., the first extension pad 126.

In some embodiments, the top surface of the first plug structure 142, i.e., the top surface of the upper portion 142a, is indented to a level lower than the top surfaces of the second dielectric layers 114 disposed at both sides thereof in the etching process for patterning the conductive layer (not shown), and also lower than the top surfaces of the second plug structure 152, i.e., the top surfaces of the upper portions 152a. Under this circumstance, a bottom surface 132a of a portion of the insulating material 132 between the extension pad, e.g., the first extension pad 126, and the first dam structure DM1 is lower than a bottom surface 132b of another portion of the insulating material 132 between the connection pads 122.

In the prior art, patterns designed near the peripheral region are usually irregular and pattern density varies in a large range. Therefore, during the manufacturing process, deviation is more likely to occur near the peripheral region than within the cell region and causes structural variation and current leakage problems, which adversely affect the producing yield and the reliability of products. According to the present invention, at least a dam structure is designed in the peripheral region, and extension pads or connection pads with enlarged gaps are optionally disposed between the dam structure and the connection pad array. Meanwhile, the dam structure is designed to be completely separated from each of the extension pads and connection pads in structure in order to ameliorate the current leakage problem.

Hereinafter, different embodiments of the present invention will be described, and in order to simplify the description, the following description will mainly focus on distinctive parts of the embodiments, and the same parts will not be repeated. In addition, the same parts in various embodiments of the present invention are labeled with the same reference numerals to facilitate cross-reference among various embodiments.

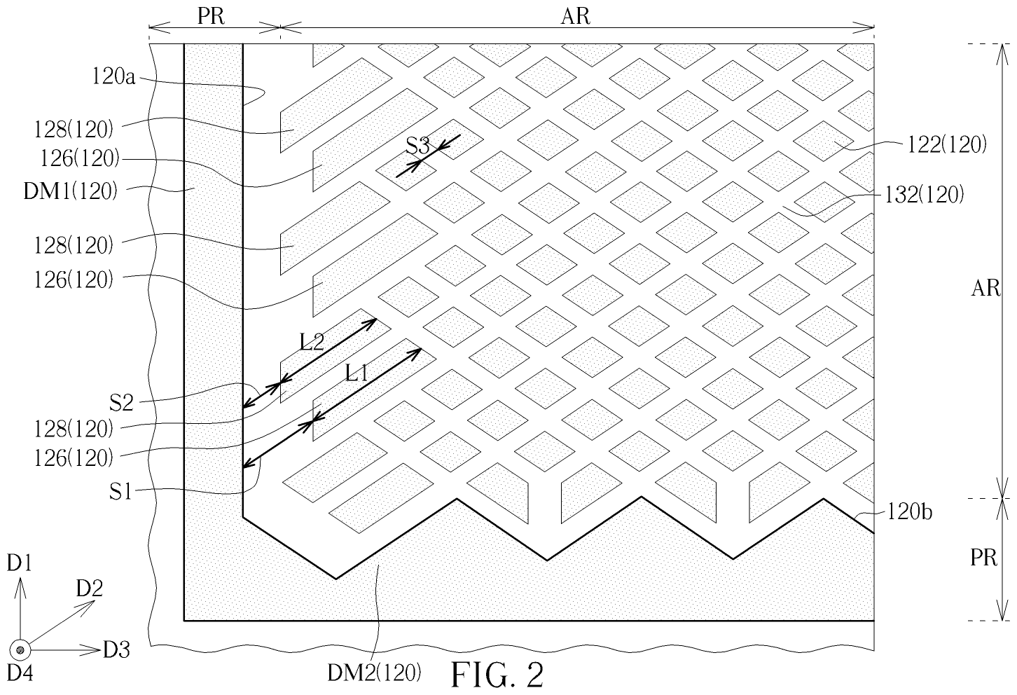

Please refer to FIG. 2, which is a schematic top view illustrating a partial area of a semiconductor structure according to another embodiment of the present invention. An embodiment of the semiconductor structure shown in FIG. 2 has substantially the same structure as that shown in FIG. 1, and the main difference therebetween is that in the semiconductor structure shown in FIG. 2, end portions of the first extension pads 126 and second extension pads 128 adjacent to the inner edge 120a are alternately arranged along the first direction D1. The distance S1 between each of the first extension pads 126 and the inner edge 120a is unequal to the distance S2 between each of the second extension pads 128 and the inner edge 120a, and both are greater than the distance S3 between connection pads 122. In some embodiments, the length L1 of each of the first extension pads 126 is substantially equal to the length L2 of each of the second extension pads 128.

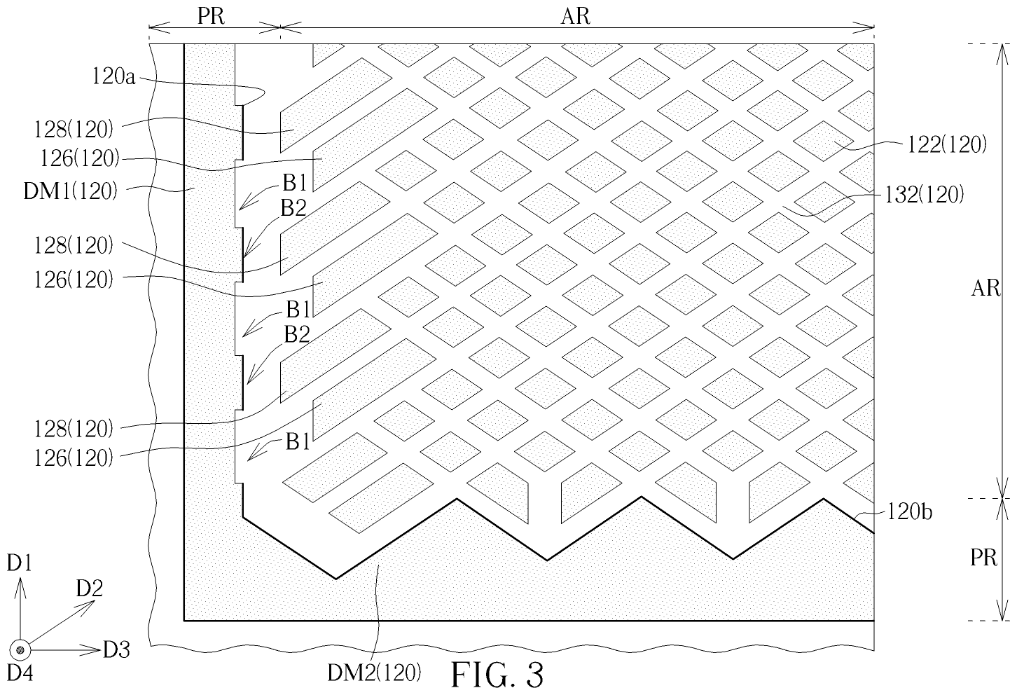

Please refer to FIG. 3, which is a schematic top view illustrating a partial area of a semiconductor structure according to a further embodiment of the present invention. An embodiment of the semiconductor structure shown in FIG. 3 has substantially the same structure as that shown in FIG. 1, and the main difference therebetween is that in the semiconductor structure shown in FIG. 3, the inner edge 120a has a wavy contour, which includes wave trough area B1 and wave crest area B2 alternately arranged along the first direction D1. The end portions of the first extension pads 126 and second extension pads 128 adjacent to the inner edge 120a are alternately arranged along the first direction D1 and correspond to the wave trough area B1 and the wave crest area B2, respectively.

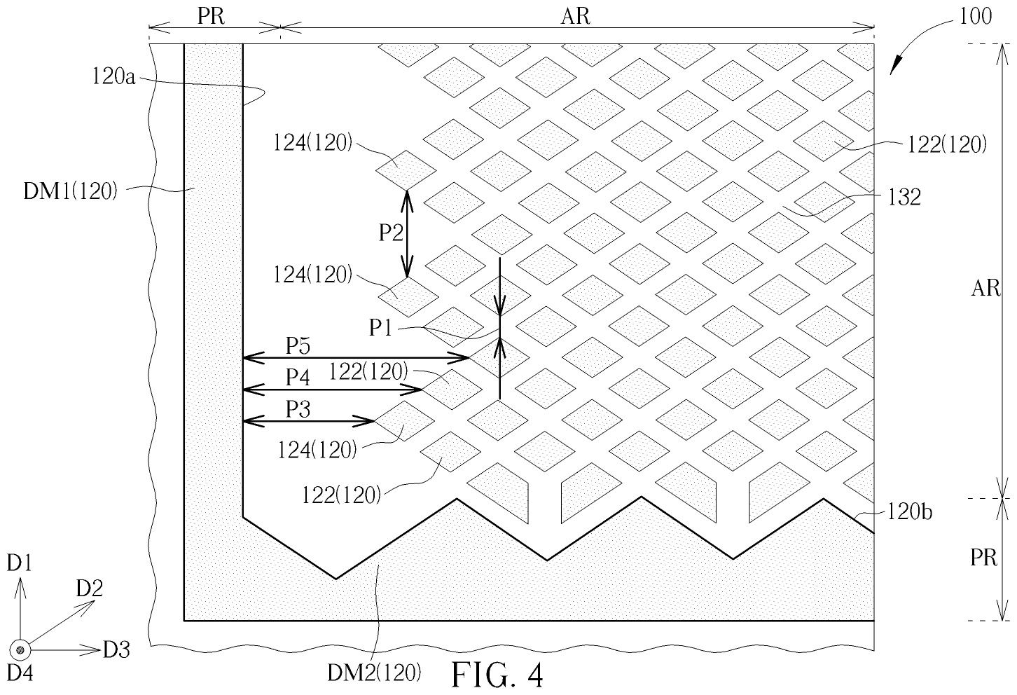

Please refer to FIG. 4, which is a schematic top view illustrating a partial area of a semiconductor structure according to yet another embodiment of the present invention. An embodiment of the semiconductor structure shown in FIG. 4 has substantially the same structure as that shown in FIG. 1, including the substrate 100, the interlayer dielectric layer 110 (not shown) disposed on the substrate 100, and the connecting layer 120 disposed on the interlayer dielectric layer 110, wherein the connecting layer 120 includes the plurality of connection pads 122 allocated along the first direction D1 and the third direction D3 to form a connection pad array and referred to as first connection pads, and a first dam structure DM1 and a second dam structure DM2 interconnected with each other and extending along the first direction D1 and the third direction D3, respectively. The first dam structure DM1 is disposed near the first side of the connection pad array, i.e., the left side as shown, and the second dam structure DM2 is disposed near the second side of the connection pad array, i.e., the right side as shown. The inner edge 120a of the first dam structure DM1 has a linear contour, and the inner edge 120b of the second dam structure DM2 has a wavy contour. The embodiment shown in FIG. 4 mainly differs from the embodiment shown in FIG. 1 in that the semiconductor structure shown in FIG. 4 does not have extension pads. Instead, connection pads 124, which are referred to as second connection pads, are disposed between the first dam structure DM1 and the connection pad array and arranged along the first direction D1. In some embodiments, as shown in FIG. 4, the connection pads 124 and the connection pads 122 are aligned to each other in the second direction D2 and the third direction D3, and have substantially the same shape and size. In the first direction D1, the shortest gap between two adjacent connection pads 122 has a distance P1, and the shortest gap between two adjacent connection pads 124 has a distance P2, wherein the distance P2 is greater than the distance P1. The connection pads 124 and the connection pads 122 disposed at the first side of the connection pad array, i.e., the left side as shown, are spaced from the inner edge 120a of the first dam structure DM1 with a third distance P3, a fourth distance P4 and a fifth distance P5 in turns. The third distance P3, the fourth distance P4 and the fifth distance P5 are different from one another. The connection pads 124 in this embodiment may function for adjusting density of patterns near the junction between the cell region AR and the peripheral region PR.

Please refer to FIG. 5, which is a schematic top view illustrating a partial area of a semiconductor structure according to still another embodiment of the present invention. An embodiment of the semiconductor structure shown in FIG. 5 has substantially the same structure as that shown in FIG. 4, including the substrate 100, the interlayer dielectric layer 110 (not shown) disposed on the substrate 100, and the connecting layer 120 disposed on the interlayer dielectric layer 110. The connecting layer 120 includes the plurality of connection pads 122 allocated to form a connection pad array and referred to as first connection pads, a first dam structure DM1 disposed near the first side of the connection pad array, i.e., the left side as shown, and the second side of the connection pad array, a second dam structure DM2 disposed near the second side of the connection pad array, i.e., the right side as shown, and connection pads 124 disposed between the first dam structure DM1 and the connection pad array and referred to as second connection pads. The embodiment shown in FIG. 5 mainly differs from the embodiment shown in FIG. 4 in that the connection pads 124 and the connection pads 122 in the embodiment shown in FIG. 5 have different shapes. For example, the connection pads 124 are strip-shaped and lengthwise extend along the second direction D2. On the contrary, the connection pads 122 are island-shaped. In the second direction D2, each of the connection pads 124 has a length L3, and each of the connection pads 122 has a length L0, wherein the length L3 is greater than the length L0.

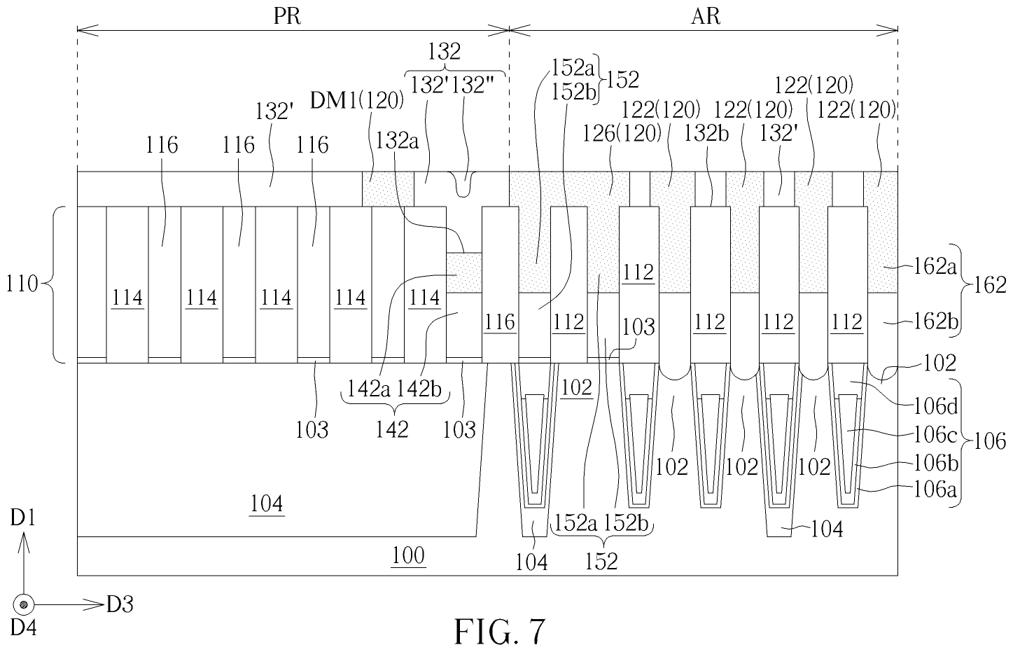

Please refer to FIG. 7, which is a cross-sectional view taken along a cut line AA′ shown in FIG. 1, which schematically illustrates a partial area of a semiconductor structure according to another embodiment of the present invention. An embodiment of the semiconductor structure shown in FIG. 7 has substantially the same structure as that shown in FIG. 6, including the substrate 100, the interlayer dielectric layer 110 (not shown) disposed on the substrate 100, and the connecting layer 120 disposed on the interlayer dielectric layer 110. The embodiment shown in FIG. 7 mainly differs from the embodiment shown in FIG. 6 in that the insulating material 132 in the embodiment shown in FIG. 7 may include a first insulating material 132′ and a second insulating material 132″ disposed on the first insulating material 132′, wherein the step coverage of the first insulating material 132′ is good enough to completely fill the gaps among the connection pads 122 and extension pads 126. The second insulating material 132″ is used for filling up the recesses existing on the surface of the first insulating material 132′, thereby avoiding poor yield resulting from unexpected residues in the recesses. Meanwhile, a relatively complete and flat surface can be provided for subsequent processes. The first insulating material 132′ and the second insulating material 132″ may include, for example but not limited to, silicon oxide (SiO₂), silicon nitride (SiN), silicon oxynitride (SiON), silicon nitride (SiCN), nitrogen-doped silicon carbide (NDC), low-k dielectric material such as fluorinated silica glass (FSG), silicon carbide oxide (SiCOH), spin-on glass, porous low-k dielectric material, organic polymer dielectric material, or a combination of the above materials. As shown in FIG. 7, a portion of the insulating material 132 disposed among the connection pads 122 includes the first insulating material 132′ and has a single-layer structure. Another portion of the insulating material 132 disposed between a dam structure, e.g., the first dam structure DM1, and extension pads, e.g., the first extension pads 126, includes the first insulating material 132′ and the second insulating material 132″ and have a dual-layer structure. Alternatively, if the second insulating material 132″ itself is multi-layered, the portion of the insulating material 132 including the second insulating material 132″ has a multi-layer structure.

To sum up, the semiconductor structures provided in the various embodiments of the present invention can ameliorate structural defect and current leakage problems that easily occur in the peripheral region due to the continuous increase of memory cell density in this art, and thus the reliability of products can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate; and
a connecting layer disposed on the substrate and comprising:
a plurality of connection pads arranged along a first direction and a third direction to form a connection pad array;
a dam structure disposed at a side of the connection pad array and extending along the first direction; and
a plurality of first extension pads and a plurality of second extension pads extending along a second direction, alternately arranged between the dam structure and the connection pad array along the first direction, and aligned with the plurality of connection pads along the second direction, wherein the plurality of first extension pads and the plurality of second extension pads are separated from the dam structure.

2. The semiconductor structure according to claim 1, wherein in the second direction, a distance between the dam structure and one of the plurality of first extension pads and the plurality of second extension pads is greater than a distance between adjacent ones of the plurality of connection pads.

3. The semiconductor structure according to claim 1, wherein an inner edge of the dam structure adjacent to the plurality of first extension pads and the plurality of second extension pads has a linear contour.

4. The semiconductor structure according to claim 1, wherein a length of one of the plurality of first extension pads is different from a length of one of the plurality of second extension pads.

5. The semiconductor structure according to claim 1, wherein end portions of the plurality of first extension pads and end portions of the plurality of second extension pads close to the dam structure are aligned with each other in the first direction.

6. The semiconductor structure according to claim 1, wherein end portions of the plurality of first extension pads and end portions of the plurality of second extension pads close to the dam structure are alternately arranged in the first direction.

7. The semiconductor structure according to claim 1, wherein in the second direction, a distance between the dam structure and one of the plurality of first extension pads is greater than a distance between the dam structure and one of the plurality of second extension pads.

8. The semiconductor structure according to claim 1, wherein an inner edge of the dam structure adjacent to the plurality of first extension pads and the plurality of second extension pads has a wavy contour, and end portions of the plurality of first extension pads and end portions of the plurality of second extension pads correspond to wave trough area and wave crest area of the wavy contour, respectively.

9. A semiconductor structure, comprising:
a substrate; and
a connecting layer disposed on the substrate and comprising:
a plurality of first connection pads arranged along a first direction and a third direction to form a connection pad array, wherein in the first direction, the plurality of first connection pads have a shortest gap with a first distance between two adjacent ones thereof;
a first dam structure disposed at a first side of the connection pad array and extending along the first direction;
a second dam structure disposed at a second side of the connection pad array and extending along the third direction; and
a plurality of second connection pads arranged between the connection pad array and the first dam structure along the first direction and separated from the first dam structure, wherein in the first direction, the plurality of second connection pads have a shortest gap with a second distance between two adjacent ones thereof, and the second distance is greater than the first distance.

10. The semiconductor structure according to claim 9, wherein in the third direction, the plurality of first connection pads and the plurality of second connection pads are interleavingly arranged at the first side of the connection pad array and spaced from the first dam structure with a third distance, a fourth distance and a fifth distance in turns, wherein the third distance, the fourth distance and the fifth distance are not equal to one another.

11. The semiconductor structure according to claim 9, wherein the plurality of second connection pads extend along a second direction, and a length of one of the plurality of second connection pads is greater than a length of one of the plurality of first connection pads.

12. A semiconductor structure, comprising:
a substrate comprising a cell region and a peripheral region adjacent to each other;
an interlayer dielectric layer comprising a first dielectric layer disposed in the cell region and a second dielectric layer disposed in the peripheral region;
a connecting layer disposed on the interlayer dielectric layer and comprising:
a plurality of connection pads disposed in the cell region;
a dam structure disposed in the peripheral region;
an extension pad disposed between the plurality of connection pads and the dam structure; and
an insulating material isolating the dam structure, the connection pads and the extension pad from one another; and
a first plug structure disposed in the second dielectric layer and between the extension pad and the dam structure, wherein a lower portion of the first plug structure is formed of a semiconductor material, an upper portion of the first plug structure is formed of a conductive material, and a top surface of the first plug structure is completely covered by the insulating material.

13. The semiconductor structure according to claim 12, wherein a bottom surface of the insulating material formed between the dam structure and the extension pad is lower than a bottom surface of the insulating material formed between the plurality of connection pads.

14. The semiconductor structure according to claim 12, wherein the insulating material formed between the dam structure and the extension pad has a multi-layer structure, and the insulating material formed between the plurality of connection pads has a single-layer structure.

15. The semiconductor structure according to claim 12, further comprising a second plug structure disposed in the first dielectric layer and having a top surface in direct contact with the extension pad, wherein the top surface of the first plug structure is lower than the top surface of the second plug structure.

16. The semiconductor structure according to claim 15, wherein an upper portion of the second plug structure is configured to be integrated with the extension pad.

17. The semiconductor structure according to claim 15, wherein a bottom surface of the second plug structure is in direction contact and electrically connected with the substrate, and a bottom surface of the first plug structure is isolated from the substrate with an insulating layer and not in direct contact with the substrate.

18. The semiconductor structure according to claim 15, wherein bottom surfaces of the first plug structure and the second plug structure are isolated from the substrate with respective insulating layers and not in direct contact with the substrate.

19. The semiconductor structure according to claim 12, further comprising an isolation structure disposed in the peripheral region of the substrate, wherein the first plug structure is disposed on the isolation structure.

20. The semiconductor structure according to claim 12, wherein a gap between the dam structure and the extension pad is larger than a gap between two adjacent ones of the plurality of connection pads.
